(19) United States
(12) Patent Application Publication
(10) Pub. No.: US 2012/0293995 A1
(43) Pub. Date: Nov. 22, 2012

(54) LED LIGHT ASSEMBLY AND METHOD FOR CONSTRUCTION THEREOF

(75) Inventor: John H. Sondericker, III, Colorado Springs, CO (US)

(73) Assignee: WYBRON, INC., Colorado Springs, CO (US)

(21) Appl. No.: 13/111,747

(22) Filed: May 19, 2011

(51) Int. Cl. F21S 4/00; F21V 5/04; F21V 11/00; H01L 33/08; F21V 7/06

(52) U.S. Cl. 362/235; 257/89; 362/249.04; 257/E33.012

(57) ABSTRACT

A light assembly, and an associated method, for illuminating a target. Light energy is generated by a plurality of LED light sources that are mounted on a substrate. Light energy generated by the LED light sources is caused to be projected towards a central focal area. The substrate is folded into a concave-shaped configuration, and the light energy generated by the LED lights is caused to be projected towards the central focal area, permitting focusing of the light energy.

The present invention relates generally to a manner by which to project LED-generated light energy. More particularly, the present invention relates to an apparatus, and an associated method, by which to construct, and provide, an LED profile, flood, or other, lamp capable of generating light energy of an intensity permitting its projection upon a target, such as a stage performer.

High-intensity light is projected using a plurality of LED light sources. A plurality of LED light sources are mounted upon a substrate, and the lamp is configured to cause the light energy generated by the LED lights to be projected through a central focus area of the lamp.

### BACKGROUND OF THE INVENTION

Lighting devices are used for many different purposes and applications. A lighting device provides light energy that provides artificial illumination to light an area or a target. Different lighting devices exhibit different light characteristics, such as different light intensities, and different light colors.

While some lighting devices exhibit static, non-changing attributes, other lighting devices are dynamically alterable in characteristics. For instance, entertainment lighting applications often times use lighting devices that have lamp outputs whose light intensities, shapes, colors, and other characteristics are alterable over wide ranges.

Significant efforts have been made to provide lighting devices that exhibit the needed range of light characteristics required of the lighting devices. Many conventional lighting devices comprise incandescent light sources. Sometimes, other types of light sources are utilized, such as high intensity discharge (HID) or florescent lamps. Incandescent light sources advantageously provide white light energy of high intensity levels but are relatively inefficient in that a significant portion of the output energy of such light sources is heat, and not light, energy. The generated heat energy must be dissipated to prevent overheating of a lighting device that includes an incandescent light source.

In contrast, gas-discharge lamps are generally more efficient, and lesser amounts of input energy are converted into light energy. The high intensity discharge, fluorescent, and other gas-discharge lamps are often times used when high level of light energy over large areas is to be provided or in which energy efficiency is a primary goal. Some gas-discharge lamps, however, exhibit a low color rendering index, which causes color distortion of areas and objects illuminated by light energy generated by such lamps.

Lighting devices are sometimes supported at, or form part of, light fixtures or assemblies. The light fixtures sometimes also support additional structure, such as light-color-changing apparatus. Light fixtures are sometimes also configured to include devices to control the light output intensity generated by the lighting devices. Variations of such devices control the light output intensity by controlling the input energy to the lighting devices. For instance, the intensity level of light energy generated by an incandescent lamp is dependent upon the voltage, current, and frequency of input energy applied to the lamp. Alteration of the input energy to an incandescent lamp, while controlling the light output intensity, also results in alteration of the color temperature and the color spectrum of the output light energy. Control of the voltage, current, or frequency of the input energy applied to high intensity discharge, and other gas-discharge, lamps is sometimes analogously made. These lamps, however, also exhibit shifting of the color temperature and color spectrum of output light energy, also caused by change in the input energy used to power the lamps. Additionally, when the light output of a gas-discharge lamp is caused to be dimmed, the light output shifts towards the blue-end of the light spectrum. Additionally, the range of possible dimming is limited. A high intensity discharge lamp is able to be dimmed down only to about 50 percent of its full output. Dimming cannot continue down to a zero output, limiting the possible change in output characteristics of the light energy.

Recent attention has been directed towards the use of light emitting diodes (LEDs) as the light sources of lighting devices. Various light devices have been developed that utilize LED light sources that generate output light energy of intensity levels that are great enough to provide illumination of objects for various applications, including stage lighting applications. The light intensity generated by a single LED light is small, but due to the size of an LED lamp, groups of the lamps can be positioned together, and the collective light output of the grouped-together lamps provides for light output that is of an acceptable intensity for many lighting applications.

The need to utilize a large number of LEDs presents various challenges. For instance, when creating a profile lamp, the light energy generated by the LEDs forming the light source must be directed towards a central focus area. This presents a challenge due to the large number of LEDs that are typically required to be used.

There is a need, therefore, to overcome this challenge, as well as other challenges, associated with use of LEDs as light sources in lighting devices.

It is in light of this background information related to lighting devices that the significant improvements of the present invention have evolved.

### BRIEF DESCRIPTION OF THE DRAWINGS

FIG. 1 illustrates a functional block diagram of a light assembly of an embodiment of the present invention.

FIG. 2 illustrates a functional representation of the light assembly shown in FIG. 1.

FIG. 3 illustrates a representation of a substrate forming part of the light assembly of FIGS. 1-2.

FIG. 4 illustrates a substrate of an exemplary embodiment of the present invention.

FIG. 5 illustrates a perspective view of the light assembly shown in FIGS. 1-3.

FIG. 6 illustrates part of a light assembly of an alternate embodiment of the present invention.

FIG. 7 illustrates a representation of another embodiment of the present disclosure.

FIG. 8 illustrates a method flow diagram representative of the method of operation of an embodiment of the present invention.

### DETAILED DESCRIPTION

The present invention, accordingly, advantageously provides an apparatus, and an associated method, for projecting LED-generated light energy.

Through operation of an embodiment of the present invention, a manner is provided by which to construct, and to provide an LED profile, flood, or other, lamp capable of generating light energy of an intensity permitting its projection upon a target, such as a stage performer.

In one aspect of the present invention, high-intensity light energy is generated and projected using a plurality of LED light sources. The plurality of LED light sources is mounted upon a substrate, and the lamp is configured to cause the light energy generated by the LED light sources to be projected through a central focus area of the lamp.

In another aspect of the present invention, the LED light sources are mounted upon the substrate in a manner to arrange the LED light sources in an arrayed configuration. The positioning of the LED light sources upon the substrate in the arrayed configuration positions the LED light sources offset from one another at the specified locations of the substrate.

In another aspect of the present invention, the substrate is formed of substrate portions, and the substrate is bent, or otherwise folded, along specified fold lines to configure the substrate into a concave configuration. In one implementation, the LED light sources are positioned upon the substrate, and then the substrate is bent or folded. In another implementation, the LED light sources are positioned upon the substrate subsequent to bending or folding of the substrate into the concave configuration.

In another aspect of the present invention, the bending or folding of the substrate into the concave configuration causes light energy generated by the light emitting diodes, when mounted on the substrate and powered with electrical energy, to project light energy that, for each of the LEDs, converges at a central focus area. That is to say, the light energy generated by each of the LEDs is caused to be projected towards a common area. By appropriate configuration of the substrate portions to define the concave configuration of the substrate, the LEDs mounted thereon are caused to be positioned at orientations that light energy generated therefrom is directed towards the central focus area.

In another aspect of the present invention, the substrate portions are of common geometric shapes, such as triangular of hexagonal shapes. The substrate is initially of a planar configuration. To reconfigure the substrate into the concave configuration, the substrate is folded along selected fold lines, defined by portions of perimeters of the geometric-shaped substrate portions.

In another aspect of the present invention, the substrate is folded or bent into an inner-spherical configuration generally conforming to a geodesic pattern in which each substrate portion defines a geodesic-pattern piece. The substrate thereby forms a “shallow bowl” shape or configuration.

In another aspect of the present invention, the LED light sources that are mounted on the substrate generate a white-colored light. In another implementation, the LED light sources are colored lights, and generate light energy of a specific color, such as red, yellow, or blue. And, in one implementation, each LED light is formed of a group of LED light sources of different colors.

In another aspect of the present invention, a gate is positioned at the focal area at which the light energy generated by the LED light sources is caused to converge. The gate defines a shape, such as a complex-shape, that is, in part, determinative of the light boundary of light generated by the light assembly.

In another aspect of the present invention, the LED light sources are mounted upon a planar substrate, and, when powered, light energy generated by the LED light sources are projected upon a parabolic reflector that causes the incident light energy thereon to be reflected towards a central focal area. The LED light sources are positioned upon the substrate in a configuration that permits light energy from each of the LED light sources to be projected in a linear direction to be incident upon the parabolic reflector and to be reflected therefrom towards the central focal area. In one implementation, the substrate is circular with a center aperture at which the central focal area is defined.

Thereby, a light assembly utilizing LED light sources as the light source is provided, implemented, for example as a profile lamp. The advantages of use of LED light sources as a light source is provided for a profile lamp, and construction is carried out in a manner that overcomes problems associated with conventional implementations.

In these and other aspects, therefore, a light assembly, and an associated method, is provided. The light assembly includes a concave-substrate. A plurality of LED light sources is positioned upon the concave-configured substrate. Each LED light source is positioned at a substrate portion of the concave-configured substrate such that, when powered, light energy generated by each LED light source is projected in a direction that converges at a central focus area.

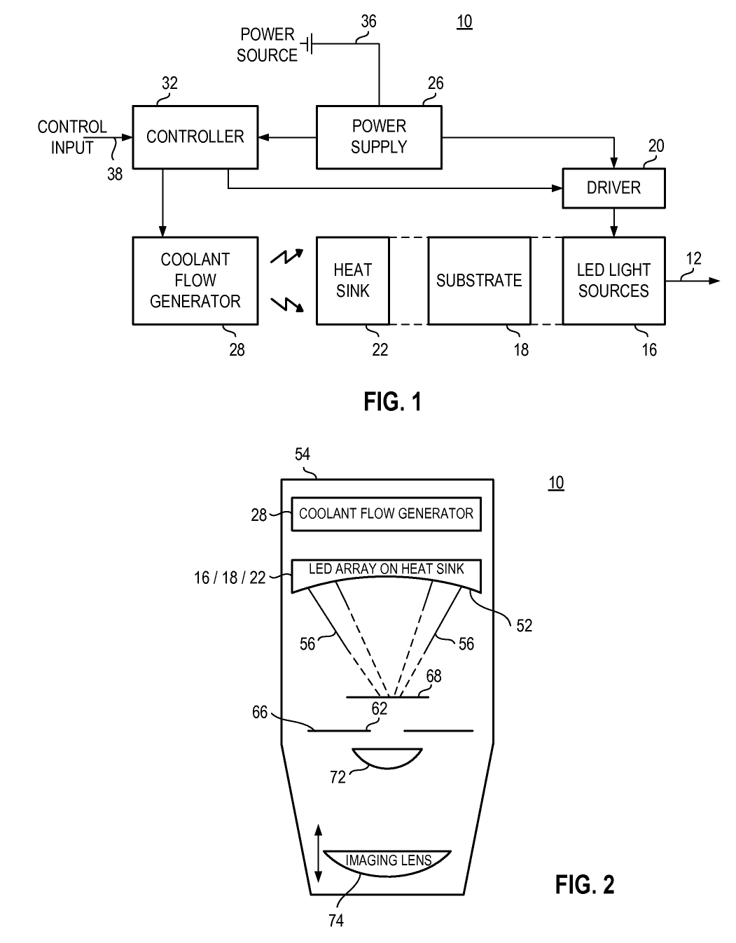

Turning first, therefore, to FIG. 1, a light assembly, shown generally at 10, operates to generate light energy that forms a lamp output 12. In the exemplary implementation, the light assembly 10 forms a profile lamp, such as a profile lamp used in stage and theatrical productions to project light upon a target or object. In other implementations, the light assembly 10 is configured and used for other purposes. While the following description of exemplary operation of the light assembly 10 shall be made with respect to its exemplary implementation, operation of the light assembly and other implementations can analogously be described.

The light assembly 10 includes an array of LED light sources 16 mounted upon a concave-configured substrate 18, an LED driver 20, a heat sink 22, a power supply 26, a coolant flow generator 28, and a controller 32.

The power supply 26 provides operative power to power both the driver 20 and the controller 32. The power provided by the power supply 26 is here sourced by an external source, provided to the power supply by way of a power-supply line 36. The power supply comprises, for instance, a public electrical grid. The power supply functions to convert the sourced power into characteristics permitting direct powering of the driver 20 and the controller 32 and, in turn, to power the LED light sources 16 and the coolant flow generator 28.

Control over operation of the light assembly is provided by the controller 32, which receives external, input commands provided to the controller by way of the lines 38. The external commands comprise, for instance, manually-selected commands or commands generated responsive to a programmatic sequence. The external commands are provided in any appropriate manner, including by way of wired connection to the controller or wireless commands sent by way of a radio interface.

The controller controls operation of the coolant flow generator 28. The coolant flow generator comprises, for instance, a coolant fan that generates coolant air flow, i.e., coolant fluid. Heat energy generated during operation of the LED light sources 16 is conducted through the substrate 18 to the heat sink 22 and dissipated therefrom. The coolant flow generated by the coolant flow generator facilitates the dissipation of the heat energy. The controller 32 also controls operation of the LED driver 20 and, hence, the LED light sources 16.

In the exemplary implementation, the LED light sources of the array are mounted upon the substrate 18, and the substrate is configured into a concave- shaped configuration. When so-configured, the light energy generated by the LED light sources of the array are caused to be projected in directions that converge at a central focal area of the light assembly.

FIG. 2 again illustrates the light assembly 10, again showing the array of LED light sources 16 mounted on a substrate 18 and a heat sink 22. The array 16, substrate 18, and heat sink 22 are represented by a single element 16/18/22 in FIG. 2. The coolant flow generator 28 is again shown to be positioned in proximity to the heat sink 22 to dissipate thermal energy generated during operation of the light assembly. The front face 52 of the element 16/18/22 is shown to be concave-configured. The LED light sources of the array 16 are mounted on the concave surface, positioned such that light energy generated during operation of the LED light sources is projected in directions indicated by the lines 56 that converge at a central focal area 62.

The illustration of the light assembly 10 shown in FIG. 2 further shows a gate 66 positioned to extend across the housing 54 of the light assembly. The gate defines an opening at the central focus area 62. Light energy generated by the LED light sources of the array are projected towards the central focus area. The opening defined by the gate 66 is of any of various shapes, including complex, geometric shapes.

The light assembly 10 of the exemplary implementation also includes a diffuser 68. The diffuser is positioned between the LED lamps and the gate and operates to diffuse light energy incident thereon. Thereby, diffused light energy is projected through the central focus area 62.

The light assembly 10 also includes a focusing lens 72 and an imaging lens 74. The focusing lens is positioned in proximity to the central focus area such that light energy passing there through is incident thereon. The focusing lens condenses, i.e., concentrates or focuses, light energy in a desired manner. And, light energy passing through the condenser is focused at the imaging lens 74. All of the elements of the light assembly 10 are housed within, or connected to, the housing 54 in the exemplary implementation.

In the exemplary implementation, the LED light sources 16 of the array are mounted upon a substrate at locations of the substrates to define the configuration of the array.

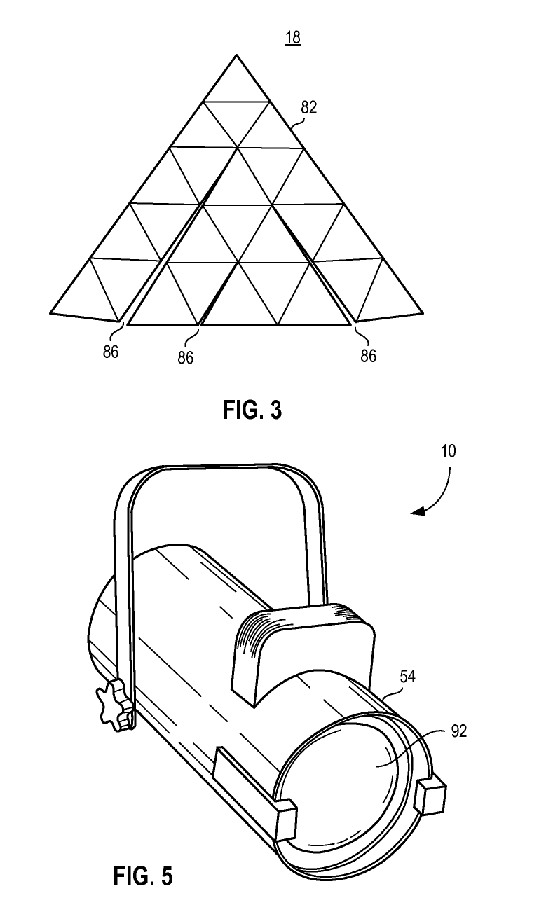

FIG. 3 illustrates a representation of a substrate 18 of an exemplary implementation. In the view shown in FIG. 3, the substrate is formed of a plurality of substrate portions 82. Each substrate portion is of a geometric shape. In the exemplary implementation, each substrate portion is triangular-shaped, that is, three-sided. In other implementations, the substrate portions are of other geometric shapes, such as, for instance, hexagonal-shaped portions. The borders of portions of selected ones of the substrate portions define fold lines about which the substrate is folded to reconfigure the substrate into a concave-configured shape. To facilitate the folding and formation of the concave-shaped configuration, cut lines 86 are formed in the substrate prior to folding of the substrate. Folding of the substrate along the fold lines positions the substrate portions 82 into a geodesic-shaped configuration, and each of the substrate portions comprises a geodesic portion of the geodesic-configured substrate.

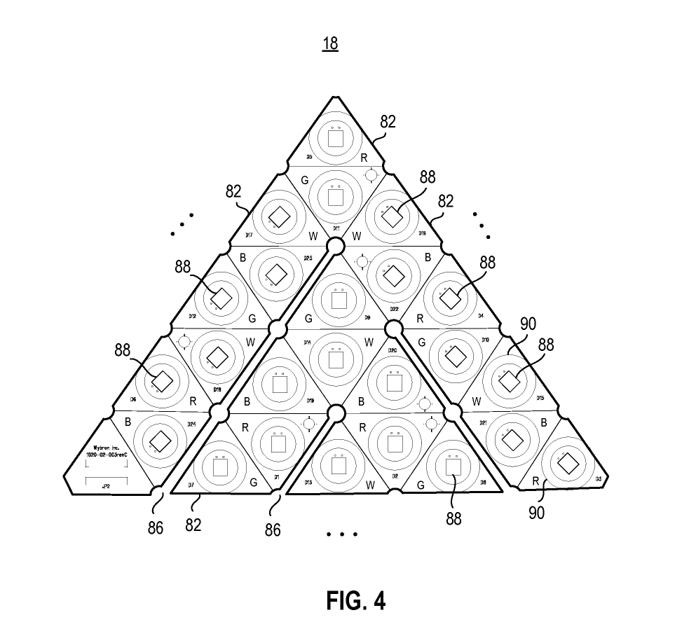

FIG. 4 illustrates a substrate 18 of an exemplary implementation, here in a planar configuration prior to bending or folding of the substrate into a concave-shaped configuration. Analogous to the representation shown in FIG. 3, the substrate is formed of a plurality of substrate portions 82 that are essentially triangular-shaped portions. And, cut lines 86 are again formed in the substrate. In the illustration of FIG. 4, patterns 88 for the LED light sources that are to be mounted on the substrate are shown. In the illustrated implementation, the LED light sources are of any of red, green, blue, or white colors. The letters R, G, B, W are printed on the substrate in the substrate portion to identify to an assembler the proper color of LED light source to mount at the associated substrate portion 82. Also, as indicated, the angular position of different ones of the LED light sources are to be mounted differ. The patterns 86 further illustrate the angular orientation of the individual ones of the LED light sources.

Additionally, sets of circular patterns 90 that encircle the patterns 88 at each of the substrate portions 82 identify to an assembler the location at which to position a collimator lens that collimates light energy generated by the associated LED light sources, when positioned and powered.

In the exemplary implementation, the LED light sources and collimator lenses are mounted on the substrate 18. Then, the substrate is placed in a reflow bath or, in other appropriate manner, the LED light sources and the collimator lenses are fixed in position, and appropriate electrical connections with the LED light sources are made. The substrate 18 thereby facilitates pick-and-place assembly operation. Once the LED light sources are soldered in position, the collimator lenses are mounted on the substrate. Then, the substrate is folded into the concave-shaped configuration. The substrate is folded along straight lines, forming straight bends.

FIG. 5 again illustrates the light assembly 10. Here, the structure shown in the prior Figures is housed within the subassembly 54 of the assembly. Light energy generated by the LED lamps is projected out of the front opening 92 of the assembly.

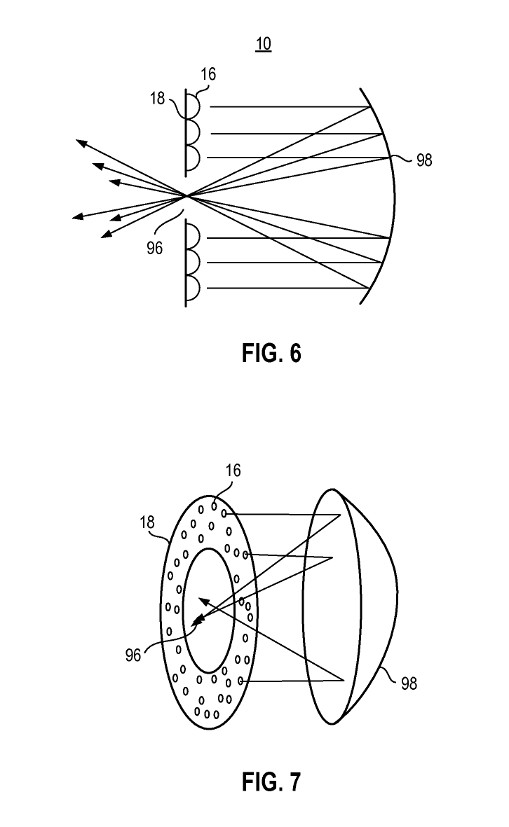

FIG. 6 illustrates portions of a light assembly 10 of an alternate implementation. The substrate 18 upon which the array of LED light sources 16 is mounted is maintained in a generally planar configuration. And, the substrate includes a center aperture 96.

In this implementation, the LED light sources 16 are not positioned to project light in the direction of the target. Rather, the LED light sources are positioned to project light in an opposite direction. A parabolic reflector 98 is positioned such that light generated by the LED light sources is incident thereon and reflected therefrom. Reflected light energy is projected in a direction to converge at a central focus area that generally corresponds in location to the aperture 96 defined by the substrate 18. The curvature of the parabolic, or other concave-shape, reflector is determinative of the positioning of the substrate so that the reflection of the light energy generated by the LED light sources is reflected towards the central aperture of the substrate. While not shown in FIG. 5, the implementation of the light assembly also optionally includes a diffuser, condenser, and imaging lens, analogous to the structure shown in the implementation illustrated in FIG. 2.

FIG. 7 also illustrates a portion of the light assembly 10 of the implementation shown in FIG. 5. In this illustration, the substrate 18 is shown to be circular in configuration with an enlarged central aperture 96. The LED light sources 16 are mounted upon a surface of the substrate, positioned such that, when powered, light energy generated by the LED light sources is projected upon the parabolic reflector 98. Reflected light energy is reflected towards the central focal area, and the substrate is positioned such that the aperture 96 defined by the substrate is positioned in proximity to the focal area.

In each of the implementations, light energy of sufficient intensity is generated through use of a plurality of LED lights in which the light energy generated by the LED lights is caused to be projected in a manner that focuses the light energy to permit its lighting of a target.

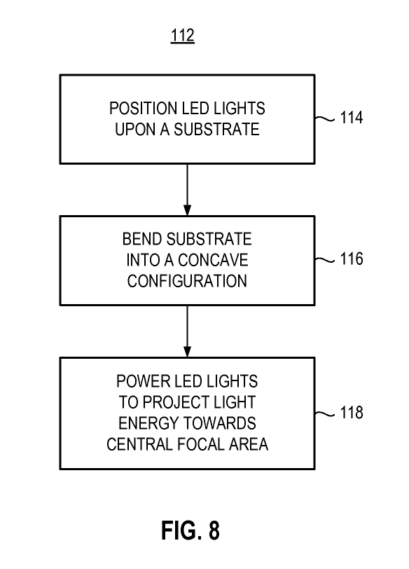

FIG. 8 illustrates a method flow diagram 112 representative of the method of operation of an embodiment of the present invention. The method is for projecting light energy upon a target.

First, and as indicated by the block 114, a plurality of LED light sources is positioned upon a substrate. Then, and as indicated by the block 116, the substrate is bent to configure the substrate into a concave configuration.

Then, and as indicated by the block 118, the LED light sources are powered to cause light energy to be directed towards a central focal area.

A profile lamp, or the like, is thereby provided that utilizes LED-light-generated light energy. The light energy is caused to be projected in a manner to permit illumination of a target, such as a stage performer or other object.

Presently preferred embodiments of the disclosure and many of its improvements and advantages have been described with a degree of particularity. The description is of preferred examples of implementing the disclosure, and the description of the preferred examples is not necessarily intended to limit the scope of the disclosure. The scope of the disclosure is defined by the following claims.

1. A light assembly comprising:
a concave-configured substrate;
a plurality of LED, light emitting diode, light sources positioned upon said concave-configured substrate, each LED light source positioned at a substrate portion of said concave-configured substrate such that, when powered, light energy generated by each LED light source is projected in a direction that converges at a central focus area.

2. The light assembly of claim 1 wherein each of the substrate portions of said concave-configured substrate comprises a folded portion having planar surface defining a perpendicular extending in a direction towards the central focal area.

3. The light assembly of claim 2 wherein each substrate portion comprises a three-sided geometric shape.

4. The light assembly of claim 3 wherein each substrate portion defines a perpendicular extending at an angle offset from a next-adjacent substrate portion.

5. The light assembly of claim 1 wherein said concave-configured substrate comprises a generally, inner-spherical-configured substrate.

6. The light assembly of claim 5 wherein said generally-inner-spherical-configured substrate conforms to a geodesic pattern.

7. The light assembly of claim 6 wherein each substrate portion comprises a geodesic-pattern piece.

8. The light assembly of claim 1 wherein the plurality of light sources comprises a plurality of colored light sources.

9. The light assembly of claim 8 wherein the plurality of colored light sources comprises a plurality of different-colored light sources.

10. The light assembly of claim 1 wherein the LED light source is offset array comprises multi-colored LED arrays.

11. The light assembly of claim 10 wherein the multi-colored LED arrays comprise tri-colored LED arrays.

12. The light assembly of claim 1 further comprising a gate configured at the focal area.

13. The light assembly of claim 12 wherein said gate comprises a complex-shaped gate.

14. The light assembly of claim 12 further comprising a diffuser positioned prior to the gate.

15. The light assembly of claim 1 further comprising a light diffuser configured to diffuse light energy generated by said plurality of LED light sources to provide diffuse light energy at the central focal area.

16. The light assembly of claim 1 further comprising a lens assembly configured to redirect light energy generated by said plurality of LED light sources subsequent to projection through the focal area.

17. A method for projecting light energy upon a target, said method comprising:
positioning a plurality of LED light sources upon a substrate;
bending the substrate to configure the substrate into a concave configuration; and
powering the LED light sources to cause light energy to be directed towards a central focal area.

18. A method for projecting light energy upon a target, said method comprising:
positioning a plurality of LED light sources upon a substrate; and
causing light energy generated during powering of the LED light sources to be directed towards a focal area.

19. The method of claim 18 further comprises bending the substrate to configure the substrate into the concave configuration.

20. The method of claim 18 wherein said causing the light energy to be directed towards a focal area comprises positioning a parabolic reflector in proximity to the LED light sources such that the light energy generated during the powering of the LED lights is reflected off of the parabolic reflector towards the focal area.
